(19) United States
(12) Patent Application Publication
(10) Pub. No.: US 2025/0286524 A1
(43) Pub. Date: Sep. 11, 2025

(54) FULLY DIFFERENTIAL SWITCHED CAPACITOR AMPLIFIER

(71) Applicant: DENSO CORPORATION, Kariya-city (JP)

(72) Inventors: Shogo KAWAHARA, Kariya-city (JP); Tomohiro NEZUKA, Kariya-city (JP); Kunihiko NAKAMURA, Kariya-city (JP); Yu FUJIMOTO, Kariya-city (JP)

(21) Appl. No.: 19/219,188

(22) Filed: May 27, 2025

Related U.S. Application Data
(63) Continuation of application No. PCT/JP2023/040413, filed on Nov. 9, 2023.

(30) Foreign Application Priority Data
Nov. 30, 2022 (JP) 2022-191817

(51) Int. Cl. H03F 3/45

(52) U.S. Cl. CPC H03F 3/45475; H03F 2203/45151; H03F 2203/45332; H03F 2203/45461

(57) ABSTRACT

A fully differential switched capacitor amplifier receives a differential analog signal from a differential input terminal, amplifies the differential analog signal, and outputs an amplified signal from a differential output terminal. The fully differential switched capacitor amplifier includes: a sampling capacitor that respectively samples the differential analog signal input from the differential input terminal; a differential input switch connected to a path for inputting the differential analog signal between the differential input terminal and the sampling capacitor; a fully differential amplifier that amplifies the differential analog signal input to the sampling capacitor; and a differential input resistor connected between the differential input switch and the sampling capacitor.

### CROSS REFERENCE TO RELATED APPLICATION

The present application is a continuation application of International Patent Application No. PCT/JP2023/040413 filed on Nov. 9, 2023, which designated the U.S. and claims the benefit of priority from Japanese Patent Application No. 2022-191817 filed on Nov. 30, 2022. The entire disclosures of all of the above applications are incorporated herein by reference.

### TECHNICAL FIELD

The present disclosure relates to a fully differential switched capacitor amplifier.

### BACKGROUND ART

An example of a conventional switched capacitor amplifier is described in a conceivable technique. In this configuration, a feedback capacitance element is connected between the inversion input terminal of the operational amplifier and the output terminal of the operational amplifier, and a switch is connected between the inversion input terminal of the operational amplifier and the output terminal of the operational amplifier.

### SUMMARY OF INVENTION

According to an example, a fully differential switched capacitor amplifier receives a differential analog signal from a differential input terminal, amplifies the differential analog signal, and outputs an amplified signal from a differential output terminal. The fully differential switched capacitor amplifier may include: a sampling capacitor that respectively samples the differential analog signal input from the differential input terminal; a differential input switch connected to a path for inputting the differential analog signal between the differential input terminal and the sampling capacitor; a fully differential amplifier that amplifies the differential analog signal input to the sampling capacitor; and a differential input resistor connected between the differential input switch and the sampling capacitor.

### BRIEF DESCRIPTION OF THE DRAWINGS

The above and other objects, features and advantages of the present disclosure will become more apparent from the following detailed description made with reference to the accompanying drawings. In the drawings:

FIG. 1 is an electrical configuration diagram of a first embodiment;

FIG. 2 is a first time chart showing the on/off states of a switch during a sample period and a hold period according to the first embodiment;

FIG. 3 is a second time chart showing the on/off states of a switch during a sample period and a hold period according to the first embodiment;

FIG. 4 is an equivalent circuit diagram of a sample period according to the first embodiment;

FIG. 5 is an equivalent circuit diagram of a hold period according to the first embodiment;

FIG. 6 is a characteristic diagram showing the change in on-state resistance before and after insertion of a differential input resistor according to the first embodiment;

FIG. 7 is an electrical configuration diagram of a second embodiment;

FIG. 8 is an electrical configuration diagram of a third embodiment;

FIG. 9 is an electrical configuration diagram of a fourth embodiment;

FIG. 10 is a block diagram of an electrical configuration of an AD converter according to a fifth embodiment;

FIG. 11 is an electrical diagram showing a part of an AD converter according to a fifth embodiment;

FIG. 12 is an electrical diagram showing a part of an AD converter according to a sixth embodiment;

FIG. 13 is an electrical diagram showing a part of an AD converter according to a seventh embodiment;

FIG. 14 is an electrical diagram showing a part of an AD converter according to an eighth embodiment;

FIG. 15 is an electrical diagram showing a part of an AD converter according to a ninth embodiment; and

FIG. 16 is an electrical diagram showing a part of an AD converter according to a tenth embodiment.

### DETAILED DESCRIPTION

Although the circuit described in the conceivable technique is configured as a single end, the inventors of the present application are considering operating the circuit as a differential circuit. At this time, if the input level becomes large, the impedance ratio between the differential input terminals becomes large, so that it is not desirable since the error caused by this feature increases. Even when the configuration described in the conceivable technique is applied, a resistor is connected between the switch and the inversion input terminal, and therefore the on-state resistance and the parasitic capacitance of the switch functions as a load even when the switch is in the off state, so that the error becomes large.

An object of the present embodiments is to provide a fully differential switched capacitor amplifier capable of reducing an error caused by the input impedance ratio of differential input terminals.

According to one aspect of the present embodiments, a pair of sampling capacitors receives a differential analog signal and starts sampling. The differential input switches are respectively connected to paths for inputting differential analog signals between the differential input terminals and the sampling capacitors. A fully differential amplifier inputs a differential analog signal to a sampling capacitor and amplifies the differential analog signal. The differential input resistors are respectively connected between the differential input switches and the sampling capacitors. Since the differential input resistors are connected between the differential input switches and the sampling capacitors, an error caused by the input impedance ratio of the differential input terminals can be reduced.

The following is a description of several embodiments of the switched capacitor amplifier with reference to the drawings. In each of the embodiments described below, the same or similar reference numerals are used to designate the same or similar configurations, and a description thereof will be omitted as necessary.

### First Embodiment

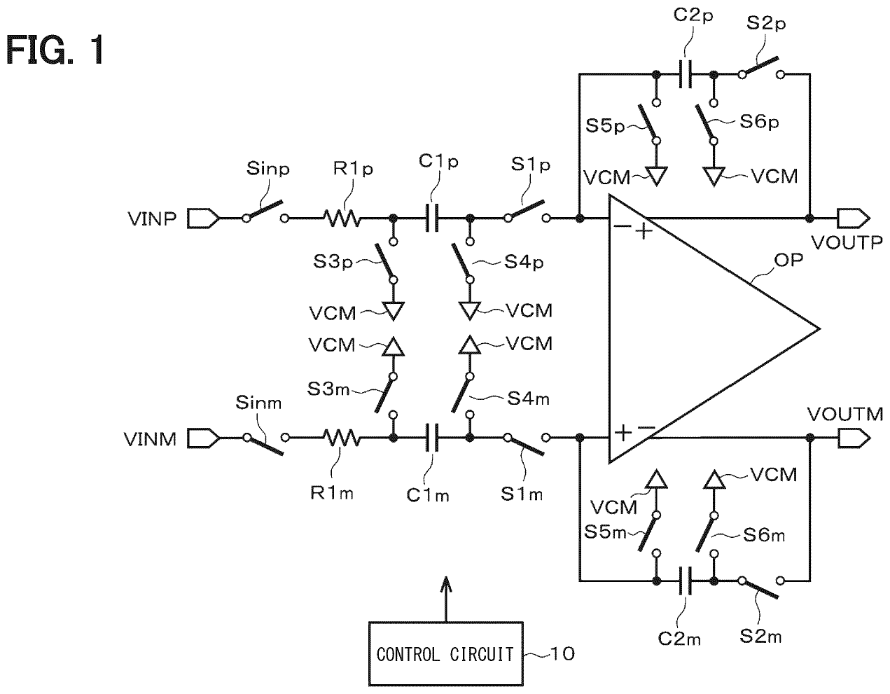

In this embodiment, a basic configuration of the switched capacitor amplifier 1 will be described. The switched capacitor amplifier 1 shown in FIG. 1 has a differential configuration including a fully differential amplifier OP of a fully differential type as a main element. In FIG. 1, the subscript p is given to the elements configured on the side of the positive input potential VINP of the full differential amplifier OP, and the subscript m is given to the elements configured on the side of the negative input potential VINM.

The switched capacitor amplifier 1 basically includes a fully differential amplifier OP, differential input switches S1p, S1m, Sinp, and Sinm, feedback switches S2p and S2m, a pair of sampling capacitors C1p and C1m, and a pair of feedback capacitors C2p and C2m. The input-side differential input switches S1p, S1m, Sinp, and Sinm are each configured by connecting in parallel between the source and the drain of a p-channel MOS transistor, and between the source and the drain of an n-channel MOS transistor. The differential input switches Sinp and Sinm are equivalent to differential input switches.

A sampling capacitor C1p and a differential input switch S1p are connected in series between the input terminal having the positive input potential VINP and the inversion input terminal of the fully differential amplifier OP. A sampling capacitor C1m and a differential input switch S1m are connected in series between the input terminal having the negative input potential VINM and the non-inversion input terminal of the fully differential amplifier OP. When the differential analog signal VINP-VINM is input, the sampling capacitors C1p and C1m sample the signal. The differential input switches S1p and S1m are each connected to a path for inputting a differential analog signal VINP-VINM.

The switches S3p and S4p are connected between electrodes of the sampling capacitor C1p and the node of the common voltage VCM, respectively. The switches S3m and S4m are connected between electrodes of the sampling capacitor C1m and the common voltage VCM, respectively. The node of the common voltage VCM is a node that is regulated to a common potential.

A switch S2p and a feedback capacitor C2p are connected in series between one of the differential output terminals and the inversion input terminal of the fully differential amplifier OP. A switch S2m and a feedback capacitor C2m are connected in series between the other of the differential output terminals and the non-inversion input terminal of the fully differential amplifier OP. The switches S5p and S6p are connected between electrodes of the feedback capacitor C2p and the node of the common voltage VCM, respectively. The switches S5m and S6m are connected between electrodes of the feedback capacitor C2m and the analog ground node, respectively.

The switches S5p, S6p, S5m, and S6m are provided to discharge the charges stored in the feedback capacitors C2p and C2m, respectively. The switches Sinp, Sinm, S1p to S6p, and S1m to S6m constitute a switching unit, which, when a differential analog signal VINP-VINM is input, charges and discharges the sampling capacitors C1p and C1m. The control circuit 10 controls the on-off switching of the switches S1p to S6p, S1m to S6m, and Sinp and Sinm to amplify the differential analog signal VINP-VINM based on the fully differential amplifier OP and the charging and discharging of the capacitors C1p, C1m, C2p, and C2m. The amplified voltage is output from the differential output terminals of the fully differential amplifier OP.

In the configuration of this embodiment, differential input resistors R1p, R1m are provided in the input path of the differential analog signal VINP-VINM between the differential input terminals and the sampling capacitors C1p, C1m, respectively. The differential input resistors R1p and R1m are connected between the differential input switches Sinp and Sinm and the sampling capacitors C1p and C1m, respectively.

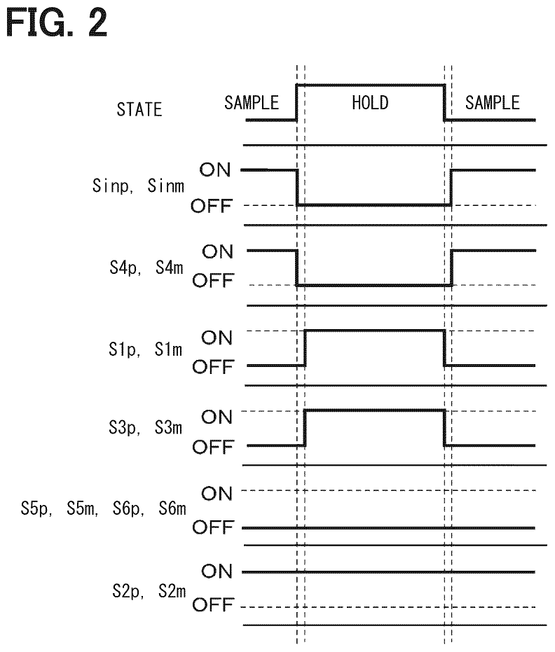

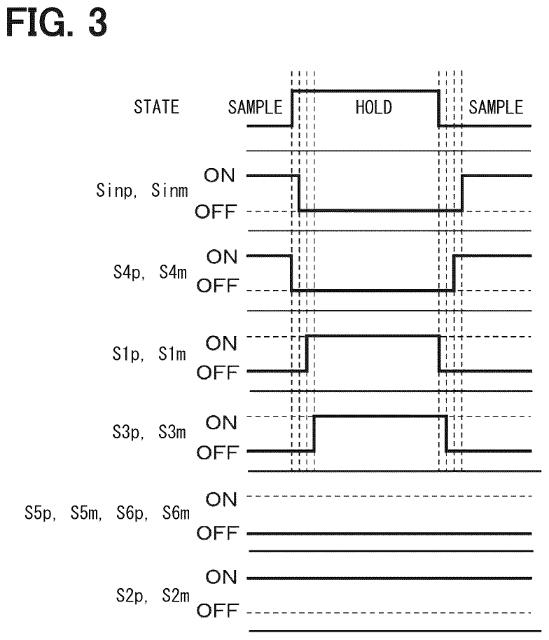

The operation of the above configuration will now be described. FIGS. 2 and 3 are timing charts showing changes in the on/off switching control signal. The control circuit 10 applies an on/off switching control signal to each of the switches Sinp, Sinm, S1p, S1m, S2p, S2m, S3p, and S3m to switch each of the switches Sinp, Sinm, S1p, S1m, S2p, S2m, S3p, and S3m on or off.

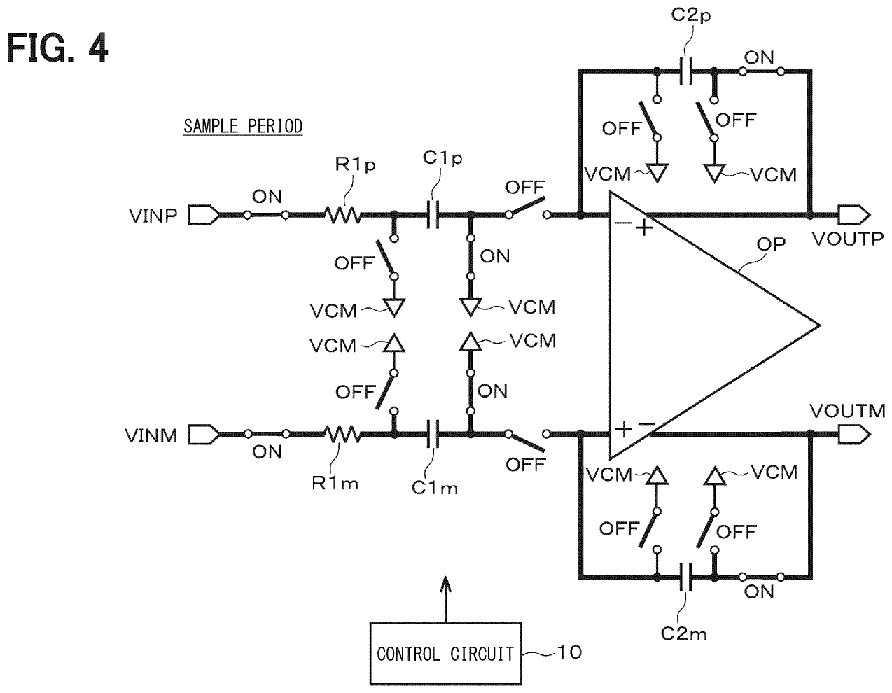

The control circuit 10 holds the switches S2p and S2m on and holds the switches S5p, S5m, S6p, and S6m off. As shown in FIGS. 2 and 3, during the sample period, the control circuit 10 controls the switches Sinp, Sinm, S4p, and S4m to be on, and controls the switches S1p, S1m, S3p, S3m, S5p, S5m, S6p, and S6m to be off. FIG. 4 illustrates the on/off states of the switches S1p to S6p and S1m to S6m during a sample period. As a result, during the sample period, the positive input potential VINP and the negative input potential VINM can be input to the sampling capacitors C1p and C1m, respectively, and charges corresponding to the positive input potential VINP and the negative input potential VINM can be sampled in the sampling capacitors C1p and C1m, respectively.

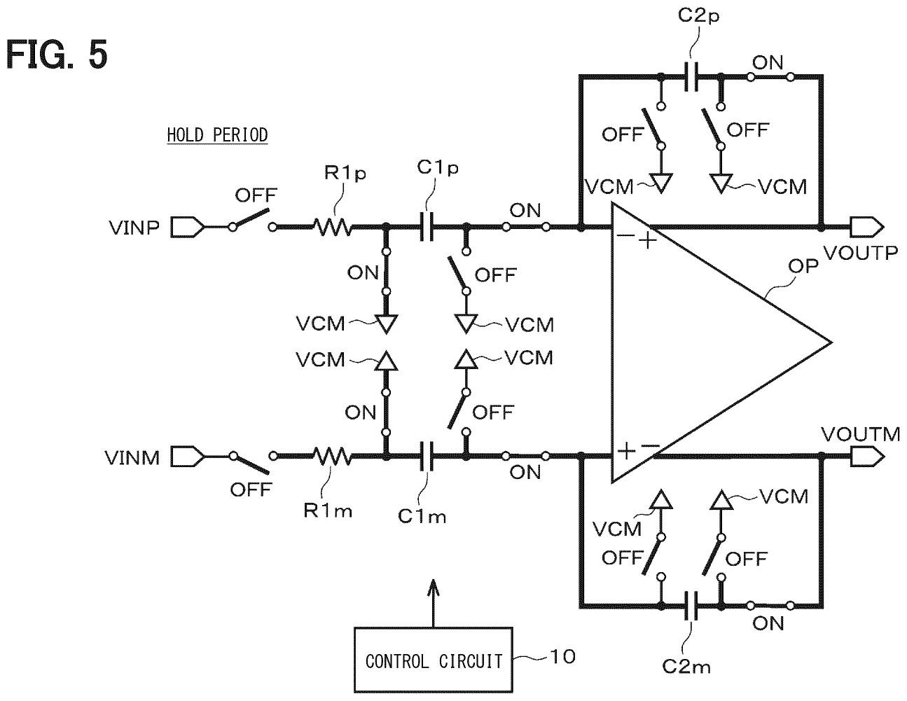

As shown in FIGS. 2 and 3, during the hold period, the control circuit 10 controls the switches S1p, S1m, S3p, S3m, S5p, S5m, S6p, and S6m to be on and controls the switches Sinp, Sinm, S4p, and S4m to be off. FIG. 5 illustrates the on/off states of the switches Sinp, Sinm, S1p to S6p, and S1m to S6m during the hold period. During the hold period, the control circuit 10 can amplify the differential analog signal VINP-VINM by inputting the charges accumulated in the sampling capacitors C1p and C1m to the fully differential amplifier OP. By repeating the sample period and the hold period, the differential analog signal VINP-VINM to be input to the sampling capacitors C1p and C1m can be amplified.

The control circuit 10 can reduce errors in case of on/off switching by providing non-overlapping on/off switching control signals to the switches Sinp, Sinm, S1p to S6p, and S1m to S6m. At this time, as shown in FIG. 2, the switches Sinp, Sinm, S4p, and S4m may be switched on and off simultaneously, and the switches S1p, S1m, S3p, S3m, S5p, S5m, S6p, and S6 may be switched on and off simultaneously, or as shown in FIG. 3, the on and off switching timings of the switches Sinp, Sinm and the switches S4p and S4m may be shifted, and the on and off switching timings of the switches S1p, S1m and the switches S3p and S3m may be shifted.

Here, in order to improve the input/output characteristics as much as possible, it is advisable to configure the circuit so as to suppress the change in settling time as much as possible even if the difference in input impedance between differentials is large. The settling time varies depending on the input impedance and the values of the sampling capacitances C1p and C1m, and varies greatly in response to changes in the input impedance of the switches Sinp and Sinm on the input side.

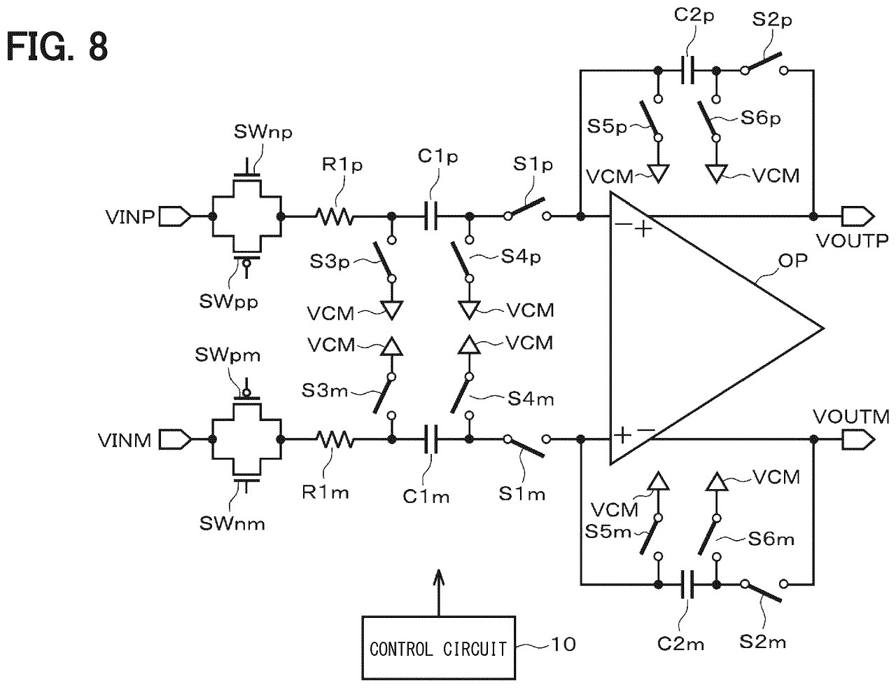

The input side switches Sinp and Sinm are each configured by connecting a p-channel type MOS transistor (hereinafter referred to as a p-MOS transistor) and an n-channel type MOS transistor (hereinafter referred to as an n-MOS transistor) in parallel. Although not shown in the drawings, in this embodiment, the connection is similar to that of the p-MOS transistors SWpp, SWnm and the n-MOS transistors SWnp, SWpm in FIG. 8 according to the third embodiment. At this time, the drains of MOS transistors are connected to the positive and negative differential input terminals. Since the voltage amplitude level of the on/off control signal is constant, the gate-source voltages of the p-MOS and n-MOS transistors change according to the voltage amplitude level of the input voltage applied to the drain of each MOS transistor, and the on-state resistance Ron changes.

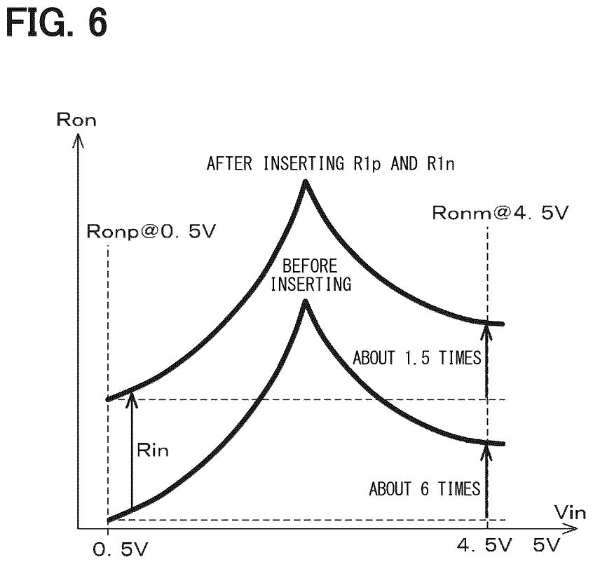

As shown in FIG. 6, for example, the case of operation in an input voltage range from 0V to 5V will be described. When the input voltage becomes lower than the intermediate voltage (=2.5 V), the gate-source voltage of the nMOS transistors constituting the switches Sinp and Sinm becomes high. This reduces the resistance value of the n-MOS transistor, and the on-state resistance Ron from the differential input terminals to the sampling capacitors C1p and C1m tends to be low. Therefore, when the input voltage is lower than the intermediate voltage, the on-state resistance Ron is determined by the on-state resistance of the n-MOS transistor having a larger effect than the on-state resistance of the p-MOS transistor. As a result, the lower the input voltage, the lower the on-state resistance Ron.

Conversely, when the input voltage is higher than the intermediate voltage (=2.5 V), the gate-source voltage of the pMOS transistors constituting the switches Sinp and Sinm increases, and the resistance value of the p-channel MOS transistor decreases. When the input voltage is higher than the intermediate voltage, the on-state resistance Ron is determined by the influence of the on-state resistance of the p-MOS transistor more than that of the n-MOS transistor. Although the on-state resistance Ron decreases as the input voltage becomes higher than the intermediate voltage, the degree of decrease is smaller than when the input voltage is lower than the intermediate voltage, as shown in FIG. 6. The impedance of the on-state resistance Ron is the lowest at both ends of these input voltages, and the impedance due to the on-state resistance Ron becomes high at intermediate voltages.

### Comparative Example

For example, a circuit configuration in which the differential input resistors R1p and R1m are not provided will be described as a comparative example. For example, if the differential input resistors R1p and R1m as in this embodiment are not inserted, the effect of the input impedance ratio between the differentials may affect the settling time between the differentials, which is undesirable. In other words, if the differential input resistors R1p and R1m are not inserted, there is a risk that the impedance ratio between the differentials will become too large.

If the impedance ratio between the differential inputs is extremely large, when the differential input switches Sinp and Sinm are turned on, the potential fluctuation is quickly contained and settled only on the side with the smaller impedance. This causes the common voltage VCM on the opposite side of the sampling capacitors C1p and C1m to fluctuate.

For example, the sizes of the p-MOS transistor and the n-MOS transistor are set to be equal, and the common voltage VCM is set to an intermediate voltage (=2.5V). It is also assumed that the positive side input potential VINP is 0.5V and the negative side input potential VINM is 4.5V. Since the positive side input potential VINP is lower than the intermediate voltage, the input impedance Ronp on the positive side of the differential input terminal is relatively small due to the dominant effect of the on-state resistance of the n-MOS transistor. Conversely, since the negative side input potential VINM is higher than the intermediate voltage, the on-state resistance of the p-MOS transistor acts dominantly on the input impedance Ronm on the negative side of the differential input terminal. In this case, the degree of decrease in the on-state resistance is relatively small, so that the differential impedance ratio becomes large, about six times, as shown in FIG. 6.

Even if the impedance ratio between differential inputs is reduced by adjusting the sizes of the p-MOS transistors and n-MOS transistors, when the threshold values of the p-MOS transistors and n-MOS transistors vary, the impedance ratio between differential inputs may become large. This causes a large difference in settling time between the positive and negative sides, so that the common voltage VCM may be easily fluctuated. When the positive side input potential VINP and the negative side input potential VINM are intermediate potentials between the maximum and minimum values, the impedance ratio is smaller than that in the previous example. It is desirable to make the impedance ratio as small as possible regardless of the values of the positive side input potential VINP and the negative side input potential VINM.

Furthermore, a configuration in which resistors (corresponding to R1p and R1m in FIG. 1) are simply connected to the input terminals of an operational amplifier (corresponding to the fully differential amplifier OP in FIG. 1) is shown in the conceivable technique. In the configuration described in the conceivable technique, a resistor is connected between the switch (corresponding to S1p in FIG. 1) and the inversion input terminal of the operational amplifier. Therefore, even when the switch is turned off, the on-state resistance and a parasitic capacitance of the switch appear as a load. This causes an error due to the parasitic components even when the switch is turned off, so that the settling time difference becomes large.

### (Technical Feature in the Present Embodiment)

In the configuration of this embodiment, the differential input resistors R1p and R1m are connected between the differential input switches Sinp and Sinm and the sampling capacitors C1p and C1m, respectively. Therefore, the input impedance can be increased overall by the resistance values of the differential input resistors R1p and R1m.

For example, FIG. 6 shows a comparison of characteristics before and after the insertion of resistors R1p and R1m. As described above, when the positive side input potential VINP is 0.5 V and the negative side input potential VINM is 4.5 V, the differential impedance ratio Ronm/Ronp can be suppressed to about 1.5 times, and the differential impedance ratio Ronm/Ronp can be significantly reduced. This makes it possible to reduce errors caused by the input impedance ratio of the differential input terminals. Since the variation in the resistance value of the resistors R1p, R1m is smaller than the variation in the on-state resistance Ron caused by the manufacturing variation of the MOS transistor, the difference in settling time caused by the variation in the resistors R1p, R1m can also be reduced.

By connecting the differential input resistors R1p, R1m between the differential input switches Sinp, Sinm and the sampling capacitors C1p, C1m, respectively, and reducing the differential impedance ratio Ronm/Ronp, it is possible to make the settling times on both sides of the differential inputs equal. This feature provides the charges between the differential inputs to be cancelled out, so that the common voltage VCM is less likely to fluctuate. This makes it possible to reduce the settling time difference between the differential inputs. The settling time difference between the differential input terminals can be improved, robustness can be improved, and the output of the switched capacitor amplifier can be made highly accurate. The load can be reduced when the differential input switches Sinp and Sinm are turned off, and interference errors can be reduced.

At this time, it is desirable that the resistance values of the differential input resistors R1p, R1m are set to be equal to or greater than the on-state resistance Ron of the differential input switches Sinp, Sinm. If the resistance values of the differential input resistors R1p, R1m are too small, either the positive side on-state resistance or the negative side on-state resistance Ron remains large, so that the settling time difference becomes large. By setting the resistance values of the differential input resistors R1p, R1m to be equal to or greater than the on-state resistance Ron of the differential input switches Sinp, Sinm, the ratio Ronm/Ronp of the on-state resistance Ron can be made as small as possible.

For example, since the applicant of the present application is currently developing a battery monitoring IC to be used for monitoring the state of a battery pack, the technology disclosed herein may be applied to the battery monitoring IC. The battery monitoring IC inputs the terminal potential of the battery cell, and also uses a multiplexer to switch and input the cell voltages of the battery cells that constitute the battery pack. In the battery monitoring IC, common mode noise due to the load current of the motor and the inverter, which are the loads on the battery cell, becomes large, and the common voltage VCM becomes more likely to fluctuate. In this situation, if the impedance ratio between the differential inputs of the differential input circuit differs significantly, the CMRR deteriorates. By using the circuit configuration according to this embodiment, the CMRR can be improved.

### Second Embodiment

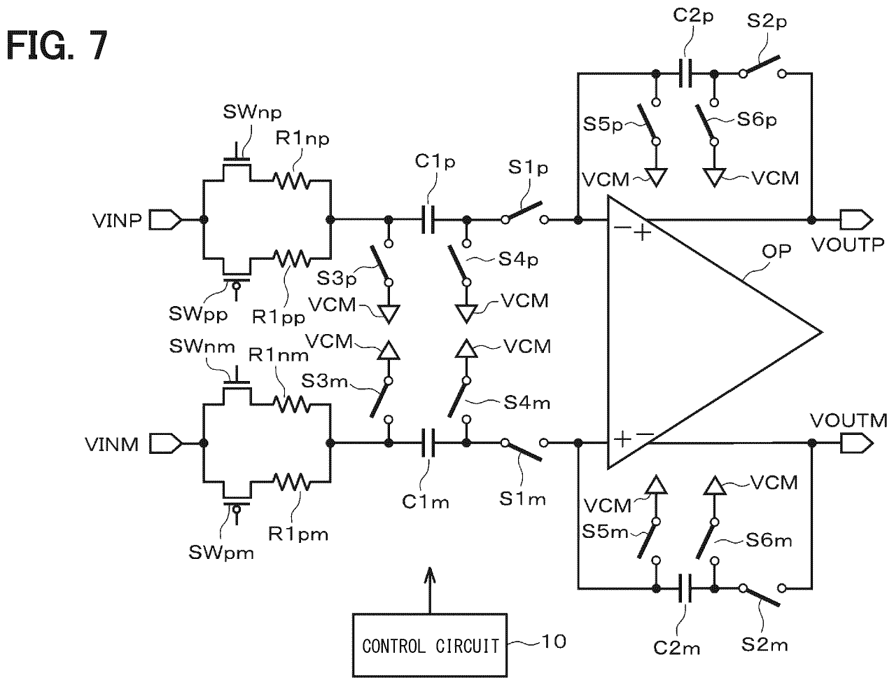

The following describes a second embodiment with reference to FIG. 7. In this embodiment, specific examples and modifications of the differential input switches Sinp, Sinm, and the resistors R1p, R1m will be described. As shown in FIG. 7, the differential input switches SWnp, SWpp and the resistors R1np, R1pp are provided in place of the differential input switch Sinp and the resistor R1p of the first embodiment. The differential input switch SWnp includes an n-channel MOS transistor, and the drain-source of the differential input switch SWnp and the resistor R1np are connected in series. The differential input switch SWpp includes an n-channel MOS transistor, and the drain-source of the differential input switch SWpp and the resistor R1pp are connected in series. The series connection circuit of the differential input switch SWnp and the resistor R1np and the series connection circuit of the differential input switch SWpp and the resistor R1pp are connected in parallel.

As shown in FIG. 7, the differential input switches SWpm, SWnm and the resistors R1pm, R1nm are provided in place of the differential input switch Sinm and differential input resistor R1m of the first embodiment. The differential input switch SWpm includes an p-channel MOS transistor, and the drain-source of the differential input switch SWpm and the resistor R1pm are connected in series. The differential input switch SWnm includes an n-channel MOS transistor, and the drain-source of the differential input switch SWnm and the resistor R1nm are connected in series. The series connection circuit of the differential input switch SWnm and the resistor R1nm and the series connection circuit of the differential input switch SWpm and the resistor R1pm are connected in parallel. The other configuration is the same as that of the first embodiment, so a description of the circuit wiring will be omitted.

When charging the sampling capacitors C1p, C1m through the differential input switches SWnp, SWpp, SWnm, SWpm in the sample period, the control circuit 10 applies an on-state control voltage to all of the differential input switches SWnp, SWpp, SWnm, SWpm to cause them to be energized. Then, the sampling capacitor C1p is charged through the resistors R1np and R1pp, and the sampling capacitor C1m is charged through the resistors R1nm and R1pm.

For this reason, it is desirable to adjust the input impedances measuring from the input side between the differential inputs so that the input impedances are equal to each other. For example, the total resistance value of the on-state resistance of the differential input switches SWnp, SWpp and the resistance values of the resistors R1np, R1pp and the total resistance value of the on-state resistance of the differential input switches SWnm, SWpm and the resistance values of the resistors R1nm, R1pm may be adjusted to be equal to each other.

In this case, even if the on-state resistances Ron of the p-channel and the n-channel MOS transistors that constitute the differential input switches SWpp, SWnp are significantly different from each other, the positive side input impedance can be adjusted by changing the resistance values of the resistors R1pp, R1np to different resistance values from each other.

On the other hand, even if the on-state resistances Ron of the p-channel and the n-channel MOS transistors that constitute the differential input switches SWpm and SWnm are significantly different from each other, the negative side input impedance can be adjusted by changing the resistance values of the resistors R1pm and R1nm to different resistance values from each other. As a result, the input impedance between the differential inputs can be adjusted individually, so that it is easy to design the circuit.

As shown in this embodiment, separate resistors R1np, R1nm may be provided for the n-channel MOS transistors that constitute the differential input switches SWnp, SWnm, and separate resistors R1pp, R1pm may be provided for the p-channel MOS transistors that constitute the differential input switches SWpp, SWpm, respectively.

### Third Embodiment

The following describes a third embodiment with reference to FIG. 8. As shown in a switched capacitor amplifier 301 in FIG. 8, the differential input switches SWnp and SWpp are connected in parallel, instead of the differential input switch Sinp in the first embodiment. The differential input switches SWpm and SWnm are provided in place of the differential input switch Sinm in the first embodiment.

The differential input switch SWnp includes an n-channel MOS transistor, and the differential input switch SWpp includes a p-channel MOS transistor. The drains and sources of the MOS transistors constituting these differential input switches SWnp and SWpp are connected in parallel.

The differential input switch SWpm includes the p-channel MOS transistors, and the differential input switch SWnm includes the n-channel MOS transistors. The drains and sources of the MOS transistors constituting these differential input switches SWpm and SWnm are connected in parallel. The other configuration is the same as that of the first embodiment, and hence the description will be omitted. Since only one resistor R1p, R1m is provided between the differential inputs, the configuration area can be reduced compared to the second embodiment.

### Fourth Embodiment

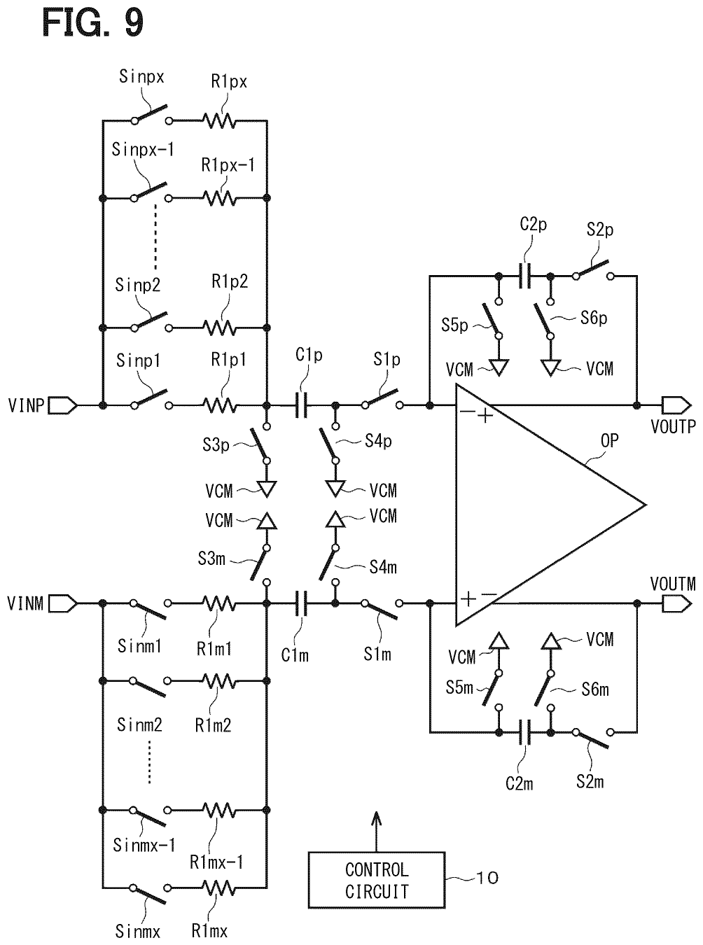

The following describes a fourth embodiment with reference to FIG. 9. As shown in a switched capacitor amplifier 401 in FIG. 9, the differential input switches Sinp1, Sinp2, . . . , Sinpx−1, Sinpx and the resistors R1p1, R1p2, are provided instead of the differential input switch Sinp and the resistor R1p in the first embodiment. The differential input switches Sinp1, Sinp2, . . . , Sinpx−1, Sinpx and the resistors R1p1, R1p2, . . . , R1px−1, R1px are connected in series, respectively, and these series connection circuits are connected in parallel.

Further, instead of the differential input switch Sinm and the differential input resistor R1m of the first embodiment, the differential input switches Sinm1, Sinm2, . . . , Sinmx−1, Sinmx and the differential input resistors R1m1, R1m2, are provided. The differential input switches Sinm1, Sinm2, . . . , Sinmx−1, Sinmx and the differential input resistors R1m1, R1m2, . . . , R1mx−1, R1mx are connected in series, respectively, and these series connection circuits are connected in parallel. The other configuration is the same as that of the first embodiment, and hence the description will be omitted.

According to the configuration of this embodiment, the differential input resistors R1p1, R1p2, . . . , R1px−1, R1px and the differential input resistors R1m1, R1m2, are connected in a multiple stage manner. Therefore, the resistance value can be finely adjusted according to the magnitude of the input voltage, and the settling time difference can be further reduced compared to the configuration of the second embodiment.

### Fifth Embodiment

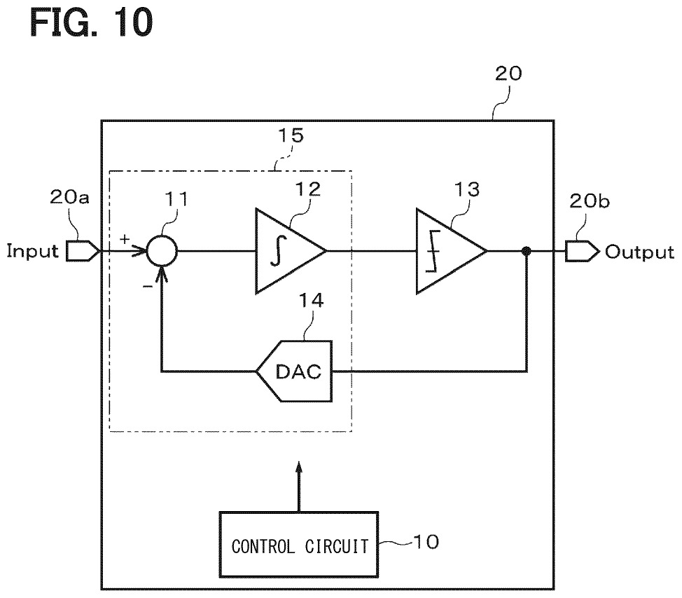

In the following embodiments, an embodiment in which the switched capacitor amplifier (e.g., 1) described in the above embodiment is applied to a AZ AD converter 20 will be described. FIG. 10 illustrates a AZ type AD converter 20. The AD converter 20 shown in FIG. 10 is a circuit that receives a differential analog signal VINP-VINM from an input terminal 20a, AD converts the differential analog signal VINP-VINM, and outputs a digital signal from an output terminal 20b, and includes a subtractor 11, an integrator 12, a quantizer 13, a DA converter 14, and a control circuit 10. The control circuit 10 includes a predetermined logic circuit.

The differential analog signal VINP-VINM is input to the integrator 12 via the subtractor 11. The integrator 12 receives and integrates the differential analog signal VINP-VINM, and outputs an integrated voltage according to the charge stored in the capacitor that constitutes the integrator 12 to the quantizer 13. When the integrated voltage is input, the quantizer 13 quantizes the integrated voltage into a plurality of levels and outputs the digital signal. The digital output value is output from an output terminal 20b and is also input to the DA converter 14.

The DA converter 14 converts the digital output of the quantizer 13 into an analog signal and feeds back and inputs the conversion output signal to the subtractor 11. The subtractor 11 subtracts the conversion output signal VR from the input differential analog signal VINP-VINM and inputs the result to the integrator 12. The integrator 12 integrates the difference signal input from the subtractor 11 and outputs the result to the quantizer 13, and the quantizer 13 quantizes the integration output and outputs the result digitally. This feedback operation is repeated.

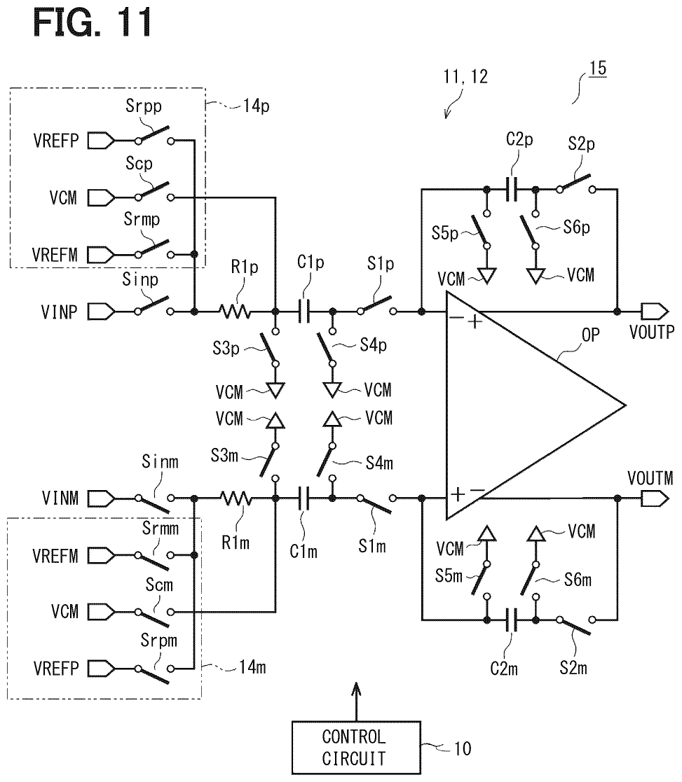

Next, a detailed configuration example of a part of the circuit 15 constituting the AD converter 20 shown in FIG. 10 will be described with reference to FIG. 11. In FIG. 11, the same components as those described in the previous embodiments (e.g., the first embodiment) are denoted by the same reference numerals. Therefore, the description of FIG. 11 will focus on the parts that are different from FIG. 1, and the description of the same functional configuration will be omitted as necessary.

The DA converter 14 inputs the conversion outputs VREFP, VCM, and VREFM of the quantizer 13 to reference potential input switches Srpp, Scp, Srmp and Srpm, Scm, and Srmm as reference potentials VREFP, VCM, and VREFM corresponding to the digital output values, respectively. The control circuit 10 selectively switches on the switches Srpp, Scp, and Srmp in accordance with the digital output value of the quantizer 13 to selectively output one of the conversion outputs VREFP, VCM, and VREFM of the quantizer 13. The selective conversion outputs VREFP, VCM, VREFM are abbreviated as conversion output VR where appropriate. The reference potential VCM shown here is set to the same potential as the common voltage VCM.

The conversion output VR of the quantizer 13 corresponds to an analog voltage obtained by D/A converting the output value of the quantizer 13, and has a relationship of, for example, “VREFP>VCM>VREFM”.

The reference potentials VREFP and VREFM are applied to the sampling capacitors C1p and C1m through the reference potential input switches Srpp, Srmp and Srpm, Srmm and the differential input resistors R1p and R1m. The reference potential VCM is applied to the common connection points of the differential input resistors R1p, R1m and the sampling capacitors C1p, C1m via the switches Scp and Scm, respectively. The integrator 12 receives the subtraction result obtained by subtracting the conversion output VR of the DA converter 14 from the input potentials VINP and VINM, and outputs an integration voltage.

In this embodiment, the other ends of the multiple reference potential input switches Srpp, Srmp are commonly connected, and a differential input resistor R1p serving as a sampling capacitance resistor is connected between the multiple reference potential input switches Srpp, Srmp and the sampling capacitor C1p. The other ends of the multiple reference potential input switches Srpm, Srmm are commonly connected, and a differential input resistor R1m serving as a sampling capacitance resistor is connected between the multiple reference potential input switches Srpm, Srmm and the sampling capacitor C1m.

A plurality of reference potential input switches Srpp, Srmp are commonly connected at a common connection point on the output side, and differential input resistors R1p, R1m are connected between the common connection point and the sampling capacitors C1p, C1m.

When multiple inputs of multiple reference potentials VREFP, VCM, and VREFM are provided for each of the sampling capacitors C1p and C1m as in this embodiment, multiple switches Srpp, Scp, and Srmp are configured. The switches Srpp, Scp, Srmp are configured by connecting n-channel and p-channel MOS transistors in parallel, and require a large circuit area, so that the distance between the switches Srpp, Scp, Srmp tends to be large.

In such a case, the impedance and the parasitic capacitance of the wiring also affect the input impedance, so that the impedance mismatch becomes larger than in the case of a configuration that employs a single differential input terminal (for example, the first to fourth embodiments described above). Even in such a case, the ratio Ronm/Ronp of the on-state resistance Ron between the differential inputs can be reduced by inserting differential input resistors R1p and R1m as shown in FIG. 11, and the settling time difference can be reduced as in the previous embodiment. Thereby, the same effect as the above embodiment can be provided.

On the positive side and the negative side, one resistor R1p, R1m is inserted collectively corresponding to the highest reference potential VREP and the lowest reference potential VREFM, respectively. This eliminates the need to connect extra resistors to the positive and negative sides, allowing for size minimization. In the energization path of the intermediate common voltage VCM, the impedance is the same on the positive side and the negative side, so there is no need to insert a resistor. Since the resistors R1p and R1m are not connected corresponding to the intermediate common voltage VCM, the operation does not slow down.

This is because when the quantizer 13 feeds back the quantization result, the analog potentials passing through the reference potential input switches Scp and Scm become equal to the intermediate common voltage VCM. That is, under conditions where there is no mismatch, the on-state resistances Ron of the reference potential input switches Scp and Scm are the same.

As in the first embodiment, it is desirable that the resistance values of the differential input resistors R1p, R1m may be set to be equal to or greater than the on-state resistance Ron of the differential input switch Sinp and the reference potential input switches Srpp, Srmp. If the resistance value is too small, the ratio of the on-state resistance Ron on the positive side or the negative side remains large, so that the error is large.

By setting the resistance values of the differential input resistors R1p, R1m to be greater than or equal to the on-state resistance Ron of the differential input switch Sinp and the reference potential input switches Srpp, Srmp, the ratio Ronm/Ronp of the on-state resistance Ron on the positive and negative sides can be reduced, so that the output has a high precision.

According to this embodiment, since the circuit connected to the input terminal of the intermediate reference potential VCM can be eliminated, the size of the circuit can be reduced compared to the embodiments described below, the circuit configuration area can be reduced, and power consumption can be reduced.

### Sixth Embodiment

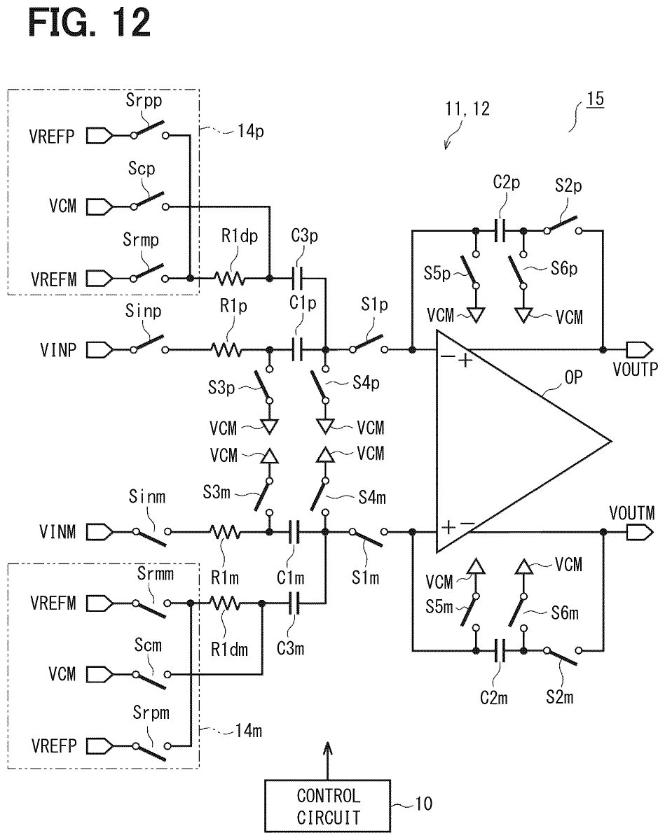

The following describes a sixth embodiment with reference to FIG. 12. In FIG. 12, the same components as those described in the previous embodiments (e.g., the first embodiment) are denoted by the same reference numerals. Therefore, the description of FIG. 12 will focus on the parts that are different from FIG. 11, and the description of the same functional configuration will be omitted as necessary.

The conversion output VR of the quantizer 13 corresponds to an analog voltage obtained by D/A converting the output value of the quantizer 13, and has a relationship of, for example, “VREFP>VCM>VREFM”. The reference potentials VREFP, VCM, and VREFM are applied to DAC capacitors C3p and C3m via reference potential input switches Srpp, Scp, Srmp and Srpm, Scm, and Srmm, respectively. The DAC capacitors C3p and C3m are used as capacitors for the reference potential terminal.

The DAC capacitors C3p and C3m and the sampling capacitors C1p and C1m have one end commonly connected, and the other end is connected to the switches S1p and S1m. As a result, the fully differential amplifier OP receives the subtraction result obtained by subtracting the conversion output VR of the DA converter 14 from the input voltage, and the integrator 12 can output an integration voltage.

In this embodiment, the other ends of the multiple reference potential input switches Srpp, Srmp are commonly connected, and a reference potential terminal resistor R1dp is connected between the multiple reference potential input switches Srpp, Srmp and the DAC capacitor C3p. The other ends of the multiple reference potential input switches Srpm, Srmm are commonly connected, and a reference potential terminal resistor R1dm is connected between the multiple reference potential input switches Srpm, Srmm and the DAC capacitor C3m.

The multiple reference potential input switches Srpp, Srmp input multiple reference potentials VREFP, VREFM, respectively, and are connected to the inversion input terminal of the fully differential amplifier OP via a DAC capacitor C3p and a switch S1p, respectively.

The DAC capacitor C3p is electrically connected to a plurality of reference potential input switches Srpp and Srmp. The DAC capacitor C3p is configured to selectively input the reference potentials VREFP, VREFM through a plurality of reference potential input switches Srpp, Srmp, and is connected between the sampling capacitor C1p and the differential input switch S1p.

The multiple reference potential input switches Srpm, Srmm input multiple reference potentials VREFP, VREFM, respectively, and are connected to the non-inversion input terminal of the fully differential amplifier OP via a DAC capacitor C3m and a switch S1m, respectively.

The DAC capacitor C3pm is electrically connected to a plurality of reference potential input switches Srpm and Srmm. The DAC capacitor C3m is configured to selectively input the reference potentials VREFP, VREFM through a plurality of reference potential input switches Srpm, Srmm, and is connected between the sampling capacitor C1m and the differential input switch S1m.

A reference potential terminal resistor R1dp is connected between the plurality of reference potential input switches Srpp, Srmp and the DAC capacitor C3p. A reference potential terminal resistor R1dm is connected between the plurality of reference potential input switches Srpm, Srmm and the DAC capacitor C3m.

It is sufficient that the reference potential terminal resistor R1dp is connected between at least one of the multiple reference potential input switches Srpp, Srmp and the DAC capacitor C3p. It is sufficient that the reference potential terminal resistor R1dm is connected between at least one of the multiple reference potential input switches Srpm, Srmm and the DAC capacitor C3m.

As shown in this embodiment, even when multiple reference potential input switches Srpp, Srmp, Srpm, and Srmm are connected to the sampling capacitors C1p and C1m, the ratio Ronp/Ronm of the on-state resistance Ron between the differential inputs can be made small by inserting resistors R1dp and R1dm for the reference potential terminals, and the settling time difference between the differential inputs can be reduced.

### Seventh Embodiment

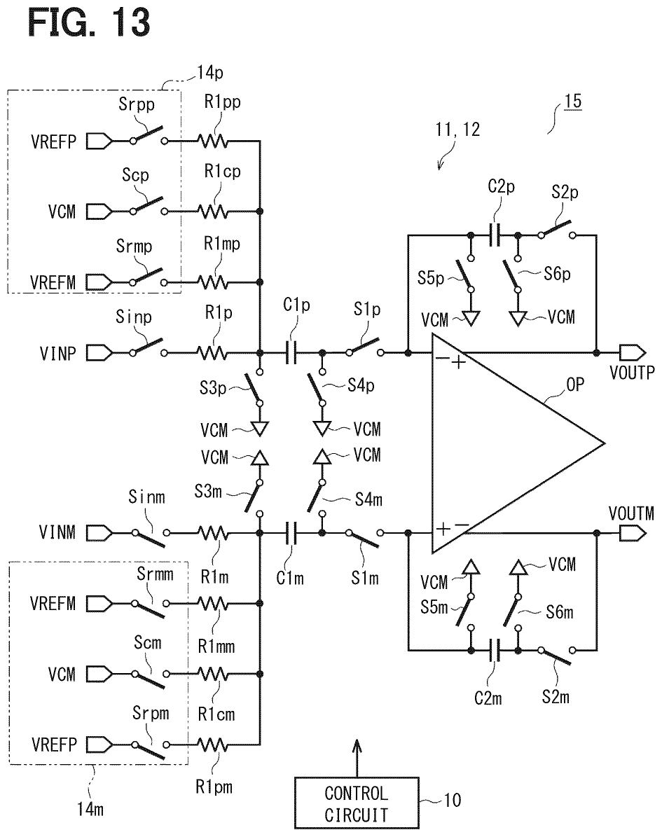

The following describes a seventh embodiment with reference to FIG. 13. As shown in FIG. 13, a plurality of reference potential input switches Srpp, Scp, Srmp input a plurality of reference potentials VREFP, VCM, VREFM, respectively, and a plurality of reference potential input switches Srpm, Scm, Srmm input a plurality of reference potentials VREFP, VCM, VREFM, respectively.

The resistors R1pp, R1cp, and R1mp are connected between the other ends of the plurality of reference potential input switches Srpp, Scp, and Srmp and the sampling capacitor C1p, respectively. A common connection point of the resistors R1pp, R1cp, and R1mp and the output terminal of the differential input resistor R1p are commonly connected. The resistors R1pm, R1cm, and R1mm are connected between the other ends of the plurality of reference potential input switches Srpm, Scm, and Srmm and the sampling capacitor C1m. A common connection point of the resistors R1pm, R1cm, and R1mm and the output end of the differential input resistor R1m are commonly connected.

When a plurality of reference potentials VREFP, VCM, and VREFM are input to the sampling capacitor C1p as in this embodiment, the reference potential input switches Srpp, Scp, and Srmp are different and therefore are disposed far from each other. Similarly, when a plurality of reference potentials VREFP, VCM, and VREFM are input to the sampling capacitor C1m, the reference potential input switches Srpm, Scm, and Srmm are different, and therefore are disposed far from each other. This causes the mismatch to be larger than in the case of a single potential terminal.

Even in this case, by inserting the resistors R1pp, R1cp, R1mp, R1pm, R1cm, and R1mm, the ratio of the on-state resistance Ron between the differential inputs can be made small, and the settling time difference between the differential inputs can be reduced.

### Eighth Embodiment

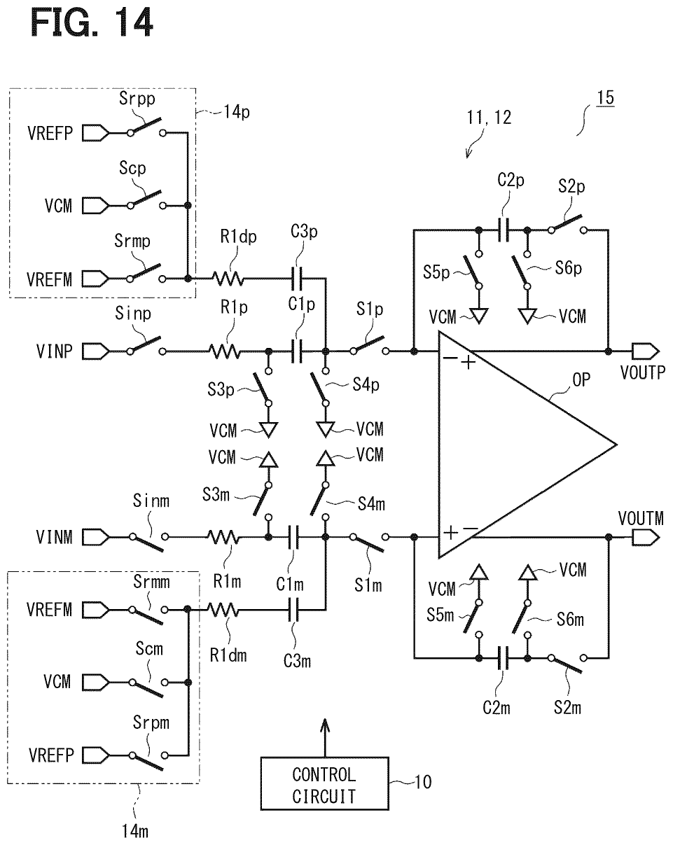

The following describes an eighteenth embodiment with reference to FIG. 14. A plurality of reference potential input switches Srpp, Scp, Srmp input a plurality of reference potentials VREFP, VCM, VREFM, respectively, and a plurality of reference potential input switches Srpm, Scm, Srmm input a plurality of reference potentials VREFP, VCM, VREFM, respectively.

The resistors R1pp, R1cp, and R1mp are connected between the other ends of the plurality of reference potential input switches Srpp, Scp, and Srmp and the sampling capacitor C1p, respectively. The resistors R1pm, R1cm, and R1mm are connected between the other ends of the plurality of reference potential input switches Srpm, Scm, and Srmm and the sampling capacitor C1m. In this embodiment as well, the size of the circuit for the common voltage VCM serving as the intermediate potential can be reduced, making it possible to reduce the area and power consumption.

### Ninth Embodiment

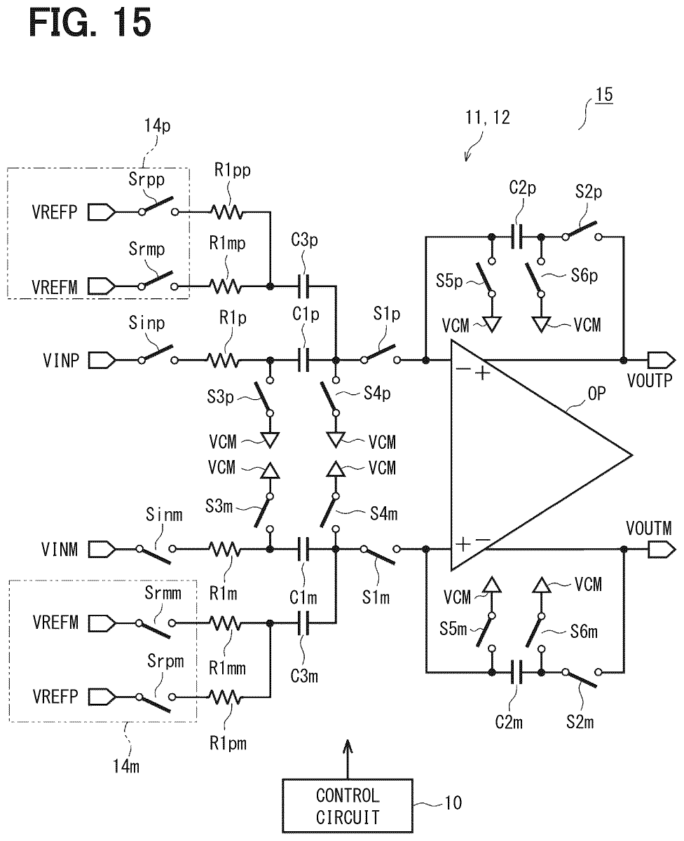

The following describes an nineteenth embodiment with reference to FIG. 15. As shown in FIG. 15, a minimum reference potential input switch Srmp and a maximum reference potential input switch Srpp are provided as reference potential input switches. The maximum reference potential input switch Srpp is connected to a maximum reference potential terminal for inputting the maximum reference potential VREFP out of the reference potentials VREFP and VREFM. The minimum reference potential input switch Srmp is connected to a minimum reference potential terminal for inputting the minimum reference potential VREFM among the reference potentials.

In this case, it is desirable to configure one maximum potential resistor R1pp connected between the maximum reference potential input switch Srpp and the DAC capacitor C3p, and one minimum potential resistor R1mp connected between the minimum reference potential input switch Srmp and the DAC capacitor C3p. It is desirable to configure one maximum potential resistor R1pm connected between the maximum reference potential input switch Srpm and the DAC capacitor C3m, and one minimum potential resistor R1mm connected between the minimum reference potential input switch Srmm and the DAC capacitor C3m.

According to this embodiment, by inserting the resistors R1pp, R1mp, R1pm, and R1mm only at the maximum and minimum potentials where the effect is greatest, it becomes unnecessary to connect extra resistors, and the size can be reduced. Furthermore, there is no input for the common voltage VCM which is an intermediate potential. In this case, there is no need to connect a resistor, and the speed does not slow down.

### Tenth Embodiment

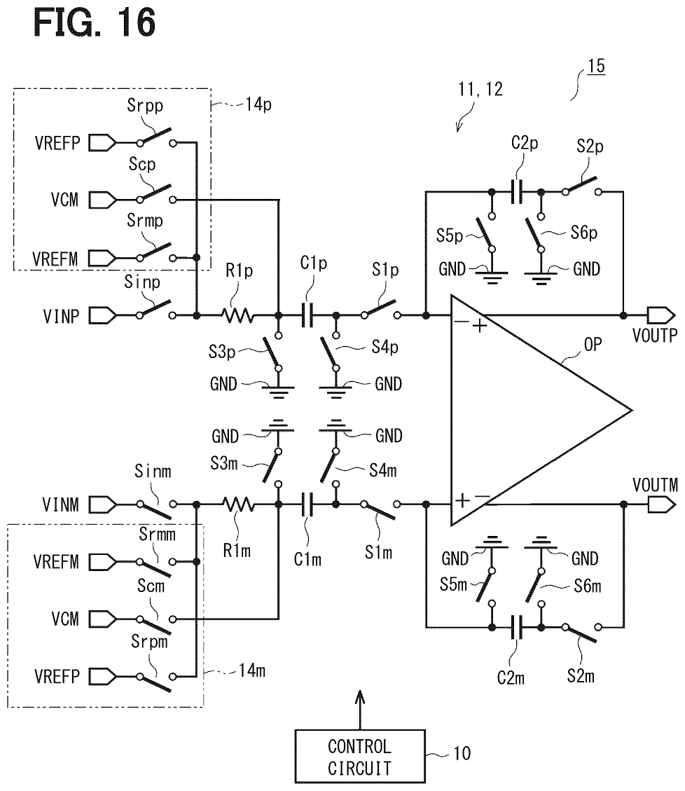

In all of the above-described embodiments, the low potential sides of the switches S3p, S4p, S3m, S4m, S5p, S5m, S6p, and S6m are connected to the common voltage VCM, but they may be connected to ground GND instead of the common mode voltage VCM. FIG. 16 shows an electrical configuration that is an alternative to the technique described in FIG. 11. Since there is no need to provide a circuit for the common voltage VCM, the circuit scale can be reduced.

### OTHER EMBODIMENTS

The present disclosure is not limited to the embodiment described above, and, for example, may be modified or expanded, which will be described.

In the above-described embodiments (for example, the fifth embodiment), a form has been shown in which a plurality of reference potentials VREFP, VCM, and VREFM are input to the reference potential input switches Srpp, Scp, Srmp and Srpm, Scm, and Srmm via the quantizer 13 and the DA converter 14, but the present embodiments are not limited to this feature. In order to add or subtract a plurality of offset voltages, the plurality of offset voltages may be input as a plurality of reference potentials to the reference potential input switches Srpp, Scp, Srmp, Srpm, Scm, and Srmm, respectively.

In the drawings, C1p and C1m are sampling capacitors, Sinp and Sinm are differential input switches, OP is a fully differential amplifier, R1p and R1m are differential input resistors, Srpp, Scp, Srmp, Srpm, Scm, and Srmm are reference potential input switches, C3p and C3m are capacitors for the reference potential terminal, R1pp, R1mp, R1pm, R1mm, R1dp, and R1dm are resistors (with resistances) for the reference potential terminal, Srpp and Srpm are maximum reference potential input switches, Srmp and Srmm are minimum reference potential input switches, R1pp, R1pm are resistors (with resistances) for the maximum potential, and R1mp and R1mm are resistors (with resistances) for the minimum potential.

In addition to the contents described in claims, the present disclosure also includes the following features.

Feature 1: A fully differential switched capacitor amplifier receives a differential analog signal from a differential input terminal, amplifies the differential analog signal, and outputs an amplified signal from a differential output terminal. The fully differential switched capacitor amplifier includes: a sampling capacitor (C1p, C1m) that respectively samples the differential analog signal input from the differential input terminal; a differential input switch (Sinp, Sinm) connected to a path for inputting the differential analog signal between the differential input terminal and the sampling capacitor; a fully differential amplifier (OP) that amplifies the differential analog signal input to the sampling capacitor; and a differential input resistor (R1p, R1m) connected between the differential input switch and the sampling capacitor.

Feature 2: The fully differential switched capacitor amplifier according to the feature 1, further includes: a plurality of reference potential input switches (Srpp, Scp, Srmp, Srpm, Scm, Srmm) for inputting a plurality of reference potentials from the differential input terminal; a reference potential terminal capacitor (C3p, C3m) electrically connected to the plurality of reference potential input switches; and a reference potential terminal resistor (R1pp, R1mp, R1pm, R1mm) connected between at least one of the plurality of reference potential input switches and the reference potential terminal capacitor. The plurality of reference potential input switches are connected to an input of the fully differential amplifier via the reference potential terminal capacitor.

Feature 3: In the fully differential switched capacitor amplifier according to the feature 2, the plurality of reference potential input switches include: a maximum reference potential input switch (Srpp, Srpm) connected to a maximum reference potential terminal for inputting a maximum potential among the reference potentials; and a minimum reference potential input switch (Srmp, Srmm) connected to a minimum reference potential terminal for inputting a minimum potential among the reference potentials. The fully differential switched capacitor amplifier further includes: a maximum potential resistor (R1pp, R1pm) connected between the maximum reference potential input switch and the reference potential terminal capacitor; and a minimum potential resistor (R1mp, R1mm) connected between the minimum reference potential input switch and the reference potential terminal capacitor.

Feature 4: The fully differential switched capacitor amplifier according to the feature 2, further includes: a plurality of reference potential input switches (Srpp, Scp, Srmp, Srpm, Scm, Srmm) for inputting a plurality of reference potentials from the differential input terminal. The plurality of reference potentials are applied to the sampling capacitor through the plurality of reference potential input switches. The fully differential switched capacitor amplifier further includes: a resistor (R1p, R1m, R1dp, R1dm; R1pp, R1cp, R1mp, R1pm, R1cm, R1mm) connected between at least one of the plurality of reference potential input switches and the fully differential amplifier.

Feature 5: In the fully differential switched capacitor amplifier according to the feature 4, the plurality of reference potential input switches (Srpp, Srmp, Scpm, Srmm) are commonly connected at a common connection point on an output side, and the resistor (R1dp, R1dm) is connected between the common connection point and the fully differential amplifier.

Feature 6: In the fully differential switched capacitor amplifier according to any one of the features 1 to 5, a resistance value of the differential input resistor is set to be equal to or greater than an on-state resistance of the differential input switch.

Although the present disclosure has been described according to the embodiments, it is understood that the present disclosure is not limited to the above-described embodiments or structures. The present disclosure includes various modification examples and equivalents thereof. In addition, while the various combinations and configurations, which are preferred, other combinations and configurations, including more, less or only a single element, are also within the spirit and scope of the present disclosure.

What is claimed is:

1. A fully differential switched capacitor amplifier that receives a pair of differential analog signals from a pair of differential input terminals, amplifies the differential analog signals, and outputs a pair of amplified signals from a pair of differential output terminals, the fully differential switched capacitor amplifier comprising:
a pair of sampling capacitors that respectively sample the differential analog signals input from the differential input terminals;
a pair of differential input switches connected to a pair of paths for inputting the differential analog signals between the differential input terminals and the sampling capacitors, respectively;
a fully differential amplifier that amplifies the differential analog signals input to the pair of sampling capacitors; and
a pair of differential input resistors connected between the pair of differential input switches and the pair of sampling capacitors, respectively, wherein:
the pair of differential input resistors and the pair of sampling capacitors are connectable in series between the pair of differential input terminals and an input of the fully differential amplifier, respectively.

2. The fully differential switched capacitor amplifier according to claim 1, further comprising:
a plurality of reference potential input switches for inputting a plurality of reference potentials from each of the differential input terminals;
a reference potential terminal capacitor electrically connected to the plurality of reference potential input switches; and
a reference potential terminal resistor connected between at least one of the plurality of reference potential input switches and the reference potential terminal capacitor, wherein:
the plurality of reference potential input switches are connected to an input of the fully differential amplifier via the reference potential terminal capacitor.

3. The fully differential switched capacitor amplifier according to claim 2, wherein:
the plurality of reference potential input switches include:
a maximum reference potential input switch connected to a maximum reference potential terminal for inputting a maximum potential among the reference potentials; and
a minimum reference potential input switch connected to a minimum reference potential terminal for inputting a minimum potential among the reference potentials,
the fully differential switched capacitor amplifier further comprising:
a maximum potential resistor connected between the maximum reference potential input switch and the reference potential terminal capacitor; and
a minimum potential resistor connected between the minimum reference potential input switch and the reference potential terminal capacitor.

4. The fully differential switched capacitor amplifier according to claim 1, further comprising:
a plurality of reference potential input switches for inputting a plurality of reference potentials from each of the differential input terminals, wherein:
the plurality of reference potentials are applied to each of the pair of sampling capacitors through the plurality of reference potential input switches, respectively,
the fully differential switched capacitor amplifier further comprising:
a resistor connected between at least one of the plurality of reference potential input switches and the fully differential amplifier.

5. The fully differential switched capacitor amplifier according to claim 4, wherein:
the plurality of reference potential input switches are commonly connected at a common connection point on an output side; and
the resistor is connected between the common connection point and the fully differential amplifier.

6. The fully differential switched capacitor amplifier according to claim 1, wherein:
a resistance value of the differential input resistor is set to be equal to or greater than an on-state resistance of each of the pair of differential input switches.
